(19) United States
(12) Patent Application Publication
(10) Pub. No.: US 2026/0076082 A1
(43) Pub. Date: Mar. 12, 2026

(54) DISPLAY DEVICE

(71) Applicant: LG Display Co., Ltd., Seoul (KR)

(72) Inventor: SungSik SON, Daegu (KR)

(73) Assignee: LG Display Co., Ltd., Seoul (KR)

(21) Appl. No.: 19/275,669

(22) Filed: Jul. 21, 2025

(30) Foreign Application Priority Data
Sep. 9, 2024 (KR) 10-2024-0122468

(51) Int. Cl. H10K 59/80

(52) U.S. Cl. CPC H10K 59/8792; H10K 59/872

(57) ABSTRACT

A display device in one example includes a display panel which includes a display area, an optical area which is enclosed by the display area and includes a through-hole, and a non-display area which encloses the display area. The display device can further include a cover member on the display panel, a support member disposed below the display panel, a light shielding member disposed below the support member, and an optical device inserted into the through-hole. The filling member is filled between the optical device and the cover member. Accordingly, light leakage which can be generated through the through-hole can be suppressed or prevented by the light shielding member.

### CROSS-REFERENCE TO RELATED APPLICATIONS

This application claims priority to Korean Patent Application No. 10-2024-0122468, filed on Sep. 9, 2024, in the Korean Intellectual Property Office, the entire disclosure of which is hereby expressly incorporated by reference into the present application.

### BACKGROUND

### Field

The present disclosure relates to a display device, and more particularly, to a display device which suppresses light leakage in an area in which a through-hole is disposed.

### Discussion of the Related Art

As the world enters the information era, a field of a display device which visually expresses electrical information signals has been rapidly developed and studies continue to improve performances of various display devices, such as a thin-thickness, a light weight, and low power consumption.

A representative display device can include a liquid crystal display device (LCD), a field emission display device (FED), an electro-wetting display device (EWD), and an organic light emitting display device (OLED).

An electroluminescent display device which is represented by an organic light emitting display device is a self-emitting display device so that a separate light source is not necessary, which is different from a liquid crystal display device. Therefore, the electroluminescent display device can be manufactured to have a light weight and a small thickness. Further, since the electroluminescent display device is advantageous not only in terms of power consumption due to the low voltage driving, but also in terms of color implementation, a response speed, a viewing angle, and a contrast ratio (CR), it is expected to be utilized in various fields.

### SUMMARY OF THE DISCLOSURE

An object to be achieved by the present disclosure is to provide a display device which suppresses light leakage in an area in which a through-hole is disposed.

Another object to be achieved by the present disclosure is to provide a display device which suppresses inflow of foreign materials in an area in which a through-hole is disposed.

Objects of the present disclosure are not limited to the above-mentioned objects, and other objects, which are not mentioned above, can be clearly understood by those skilled in the art from the following descriptions.

According to an aspect of the present disclosure, a display device includes a display panel which includes a display area, an optical area which is enclosed by the display area and includes a through-hole, and a non-display area which encloses the display area, a cover member on the display panel, a support member disposed below the display panel, a light shielding member disposed below the support member, and an optical device inserted into the through-hole, and the filling member is filled between the optical device and the cover member..

According to another aspect of the present disclosure, a display device includes a display panel which includes a display area, an optical area which is enclosed by the display area and includes a through-hole, and a non-display area which encloses the display area, a cover member on the display panel, an adhesive layer which bonds the display panel and the cover member and includes an opening overlapping the through-hole, a light shielding member which includes a first part which is disposed below the display panel and has a first hole disposed so as to overlap the through-hole, a second part which protrudes from the first part toward the through-hole below the adhesive layer and includes a second hole which is concentric with the first hole, and a third part which connects the first part and the second part, and a filling member which fills the opening and a side surface of the second part. A width of the first hole is smaller than a width of the through-hole and is larger than a width of the second hole and an optical device which is inserted into the first hole is included in the display device.

Other detailed matters of the example embodiments of the present disclosure are included in the detailed description and the drawings.

According to aspects of the present disclosure, in an optical area in which a through-hole is disposed, a light shielding member is disposed on a side surface of the through-hole to suppress the light leakage which occurs through the through-hole.

According to aspects of the present disclosure, an empty space between an optical device which is inserted into the through-hole and a cover member is filled with a filling member to suppress the inflow of foreign materials, such as dust, or moisture, through a through-hole, to the upper portion of the optical device, thereby improving a reliability of a display device.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram illustrating a display device according to an example embodiment of the present disclosure;

FIG. 2 is a front view of a display device according to an example embodiment of the present disclosure;

FIG. 3 is a rear view of a display device according to an example embodiment of the present disclosure;

FIG. 4 is a view schematically illustrating a circuit configuration of a sub pixel according to example embodiments of the present disclosure;

FIG. 5 is a perspective view taken along A-A′ of FIG. 2;

FIG. 6 is a cross-sectional view taken along A-A′ of FIG. 2;

FIG. 7 is a perspective view of a display device according to another example embodiment of the present disclosure; and FIG. 8 is a cross-sectional view of a display device according to another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately”or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure. Further, the term “can” fully encompasses all the meanings and coverages of the term “may” and vice versa.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various example embodiments of the present disclosure will be described in detail with reference to the accompanying drawings. All the components of each display device/apparatus according to all embodiments of the present disclosure are operatively coupled and configured.

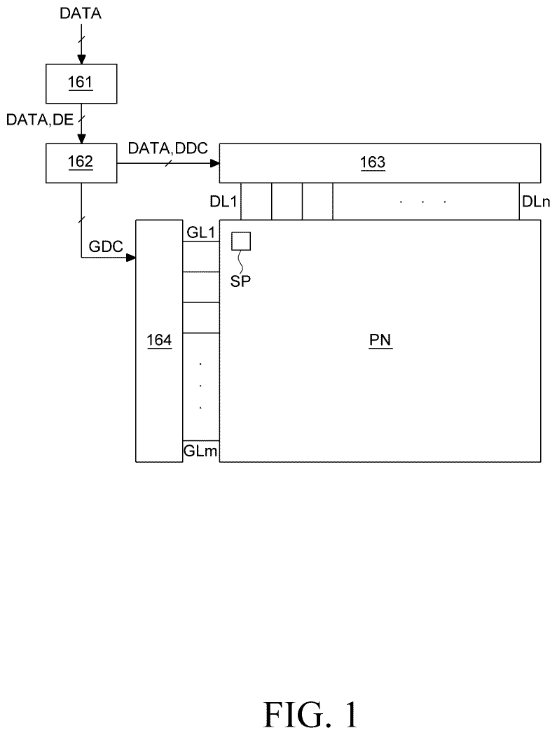

FIG. 1 is a block diagram of a display device according to an example embodiment of the present disclosure.

Referring to FIG. 1, the display device according to example embodiments of the present disclosure can include an image processor 161, a timing controller 162, a data driver 163, a scan/gate driver 164, and a display panel PN.

The image processor 161 can output a data enable signal DE together with a data signal DATA supplied from the outside.

Further, for example, the image processor 161 can output one or more of a vertical synchronization signal, a horizontal synchronization signal, and a clock signal in addition to the data enable signal DE.

The timing controller 162 can be supplied with the data signal DATA together with a driving signal including the data enable signal DE or the vertical synchronization signal, the horizontal synchronization signal, and the clock signal, from the image processor 161. Further, the timing controller 162 can output a gate timing control signal GDC for controlling an operation timing of the scan driver 164 and a data timing control signal DDC for controlling an operation timing of the data driver 163, based on the driving signal.

The data driver 163 samples and latches the data signal DATA supplied from the timing controller 162 in response to the data timing control signal DDC supplied from the timing controller 162 to convert the data signal into a gamma reference voltage and output the converted gamma reference voltage. The data driver 163 can output the data signal DATA through data lines DL1 to DLn, where n can be a real number such as a positive integer. The data driver 163 can be formed as an integrated circuit (IC).

Further, the scan driver 164 can output the scan signal in response to the gate timing control signal GDC supplied from the timing controller 162. The scan driver 164 can output the scan signal through gate lines GL1 to GLm, where m can be a real number such as a positive integer. The scan driver 164 can be formed as an integrated circuit (IC) or formed in the display panel PN in a gate in panel GIP manner.

The display panel PN can display images in response to the data signal DATA and the scan signal supplied from the data driver 163 and the scan driver 164.

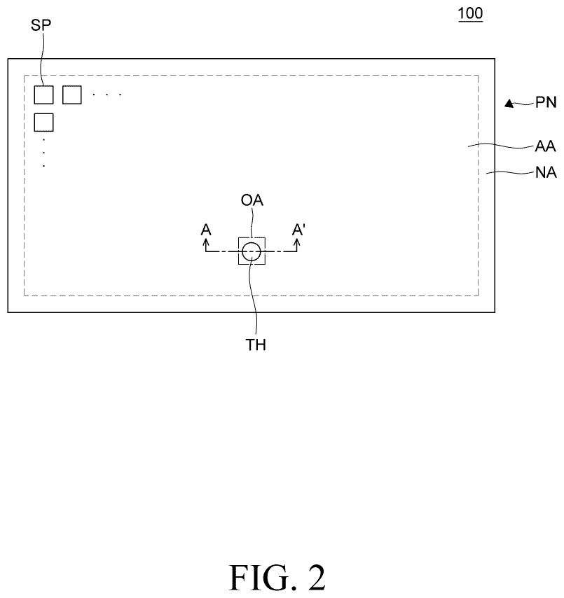

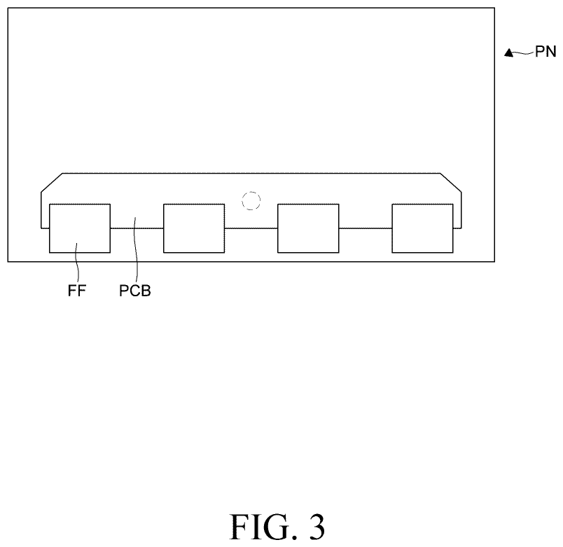

The display panel PN can include a plurality of sub pixels SP which display an image. The display panel PN will be described in detail with reference to FIGS. 2 and 3 to be described below.

For example, each sub pixel SP (or pixel or the like) can include a red sub pixel, a green sub pixel, and a blue sub pixel or include a white sub pixel, a red sub pixel, a green sub pixel, and a blue sub pixel. Each sub pixel SP can have one or more different emission areas according to an emission characteristic.

FIG. 2 is a front view of a display device according to an example embodiment of the present disclosure. FIG. 3 is a rear view of a display device according to an example embodiment of the present disclosure. For the convenience of description, in FIGS. 2 and 3, among various components of the display device 100, a display panel PN, a flexible circuit film FF, and a printed circuit board PCB are illustrated.

Referring to FIGS. 2 and 3, the display panel PN can include a display area (or active area) AA, an optical area OA which is enclosed by the display area AA and includes a through-hole TH, and a non-display area (or non-active area) NA which encloses the display area AA. The non-display area NA can surround the display area AA entirely or only in part(s).

The display area AA is an area where a plurality of pixels is disposed to substantially display images in the display panel PN.

One or each pixel can include a plurality of sub pixels SP. In the display area AA, a plurality of sub pixels SP and a circuit for driving the plurality of sub pixels SP can be disposed. The plurality of sub pixels SP is a minimum unit which configures the display area AA and each sub pixel SP can be configured to emit light of a specific wavelength band. For example, each of the sub pixels SP can be configured to emit red light, green light, blue light, or white light. A display element can be disposed in each of the plurality of sub pixels SP. For example, an organic light emitting diode which includes an anode, an emission layer, and a cathode can be disposed in each of the plurality of sub pixels SP, but it is not limited thereto. Further, a circuit for driving the plurality of sub pixels SP can include a driving element and a wiring line. For example, the circuit can be configured by a thin film transistor, a storage capacitor, a gate line, and a data line, but is not limited thereto.

The optical area OA is an area which is disposed in the display area AA to be enclosed by the display area AA and has a through-hole TH disposed therein. In the display panel PN, the through-hole TH is disposed in the display area AA to reduce a bezel area which is a non-display area NA and maximize the display area AA. A product with a design which maximizes the display area AA is aesthetically preferable by maximizing the user's screen immersion.

The through-hole TH can be disposed so as to correspond to an optical device. The optical device can be a device which receives light which passes through the display panel PN to perform a predetermined function according to received light. Therefore, the optical device can be disposed so as to overlap the through-hole TH of the display panel PN. The optical device can be a camera or various sensors, for example, but is not limited thereto, and can include all devices which perform a predetermined function according to light. In the meantime, the optical device is disposed below the display panel PN so that it is not visible to a user. For example, when the optical device is a camera, the camera is disposed on a rear surface of the display panel PN and captures an object in front of the display device 100, rather than an object in the rear of the display device 100.

One through-hole TH can be provided, but is not limited thereto and various numbers of through-holes can be disposed. For example, one or two through-holes are disposed in the display area AA so that a camera is disposed in a first hole and a distance sensing sensor or a face recognition sensor, and a wide-angle camera can be disposed in a second hole. As a variation, different units/components/devices can be disposed in one or more through-holes.

In the non-display area NA, an image is not substantially displayed and various wiring lines and circuits for driving a display element of the display area AA are disposed. The non-display area NA can be an area extending from the display area AA, but is not limited thereto and can be an area enclosing the display area AA. For example, in the non-display area NA, a link line which transmits signals to the plurality of sub pixels and circuits of the display area AA, a gate-in-panel (GIP) line, or a driving IC, such as a gate driver or a data driver, can be disposed. Further, a pad unit for connection with the flexible circuit film can be disposed on one side portion of the non-display area NA. The pad unit can be configured by a plurality of pad electrodes.

Referring to FIG. 3, the flexible circuit film FF is attached onto a rear surface of the display panel PN. The flexible circuit film FF transmits various signals from the printed circuit board PCB to the display panel PN. At this time, in the flexible circuit film FF, a driving circuit (for example, an IC chip) can be mounted. The driving circuit generates a data signal or a gate signal corresponding to a driving power or various signals which are transmitted from the printed circuit board PCB and supplies the data signal or the gate signal to a thin film transistor formed on the display panel PN. To this end, the driving circuit can include both a data driver which generates a data signal and a gate driver which generates a scan signal, or the data driver and the gate driver can be separated from each other. For example, the flexible circuit film FF and the printed circuit board PCB can be fixed to the rear surface of the display panel PN by a tape. Therefore, as seen from the top of the display panel PN, circuit elements, such as the driving circuit and the printed circuit board PCB may not be visible. Accordingly, the size of the non-display area NA which is visible from the top of the display device 100 is reduced to implement a narrow bezel.

The printed circuit board PCB is attached to the flexible circuit film FF. The printed circuit board PCB transmits various signals to a thin film transistor formed on the display panel PN. For example, signal lines which transmit various signals, such as a driving signal, a control signal, and a data signal, are formed in the printed circuit board PCB. An optical device can be disposed in an area corresponding to the through-hole TH of the display panel PN on the printed circuit board PCB and the optical device disposed on the printed circuit board PCB can be inserted into the through-hole TH of the display panel PN. In the meantime, the printed circuit board PCB can be referred to as a source printed circuit board S-PCB in which the data driver is mounted.

The display device 100 can further include various additional elements to generate various signals or drive the pixel in the display area AA. The additional elements for driving the pixels can include an inverter circuit, a multiplexer, or an electrostatic discharge (ESD) circuit. The display device 100 can further include an additional element associated with a function other than a function of driving a pixel. For example, the display device 100 can further include additional elements which provide a touch sensing function, a user authentication function (for example, fingerprint recognition), a multilevel pressure sensing function, or a tactile feedback function. The above-mentioned additional elements can be located in an external circuit which is connected to the non-display area NA and/or the connecting interface.

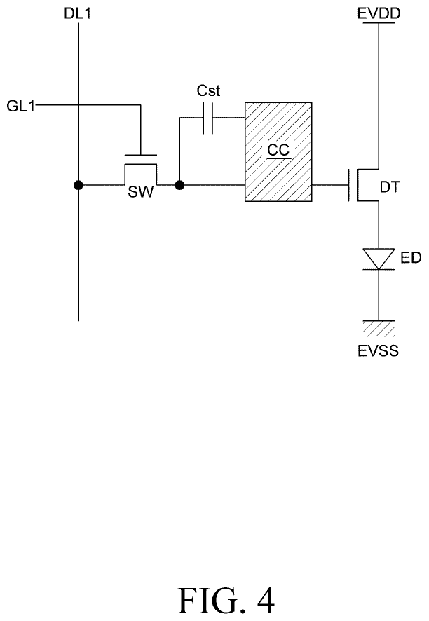

FIG. 4 is a view schematically illustrating a circuit configuration of a sub pixel according to example embodiments of the present disclosure. Each of one or more of all sub-pixels of the display panel according to various embodiments of the present disclosure can have the circuit configuration of FIG. 4.

Referring to FIG. 4, in one sub pixel, a switching thin film transistor SW, a driving thin film transistor DT, a capacitor Cst, a compensation circuit CC, and an organic light emitting diode ED can be included.

For example, the switching thin film transistor SW can perform a switching operation such that a data signal supplied through a first data line DL1 is stored in a capacitor Cst as a data voltage in response to a scan signal supplied through a first gate line GL1. Further, for example, the driving thin film transistor DT operates to flow a driving current between a first power line EVDD (a high potential voltage) and a second power line EVSS (a low potential voltage) in accordance with the data voltage stored in the capacitor Cst. Further, the organic light emitting diode ED can operate to emit light in accordance with a driving current formed by the driving thin film transistor DT.

The compensation circuit CC is a circuit added in the sub pixel to compensate for a threshold voltage of the driving transistor DT. The compensation circuit CC can be configured by one or more thin film transistors. A configuration of the compensation circuit CC can vary depending on an external compensating method.

The sub pixel illustrated in FIG. 4 is configured by a 2T (transistor) 1C (capacitor) structure including a switching thin film transistor ST, a driving thin film transistor DT, a capacitor Cₛₜ, and a light emitting diode ED. When the compensation circuit CC is added, the sub pixel can be configured in various forms, such as 3T1C, 4T2C, 5T2C, 6T1C, 6T2C, 7T1C, and 7T2C.

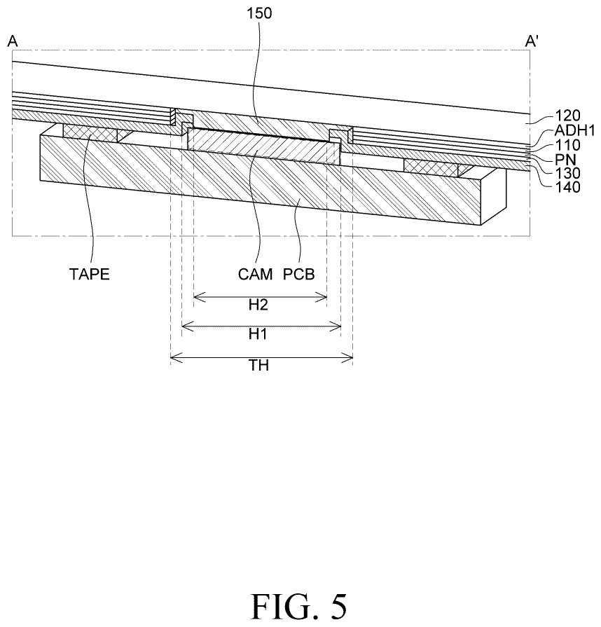

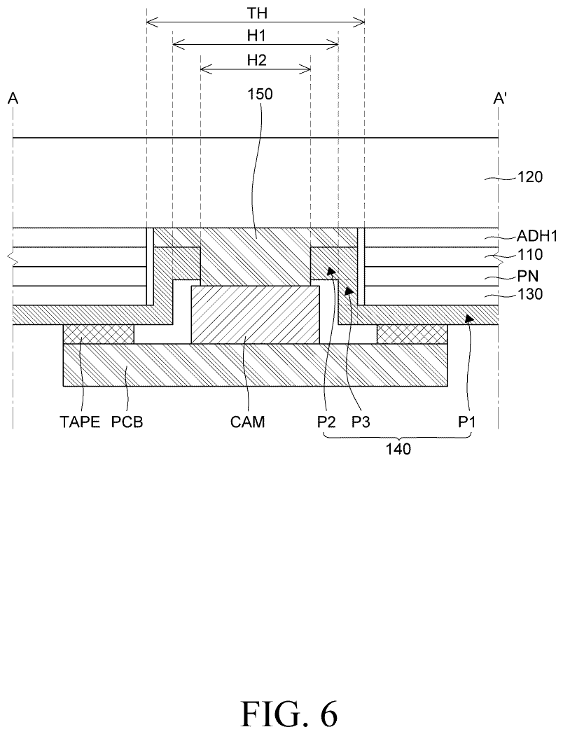

Hereinafter, the display device 100 according to one or more embodiments of the present disclosure will be described in more detail with reference to FIGS. 5 and 6.

FIG. 5 is a perspective view taken along A-A′ of FIG. 2. FIG. 6 is a cross-sectional view taken along A-A′ of FIG. 2.

Referring to FIGS. 5 and 6, the display device 100 can include a cover member 120, a polarization layer 110, a display panel PN, a support member 130, a light shielding member 140, a filling member 150, an adhesive layer ADH1, and an optical device CAM.

First, the display panel PN can include a flexible substrate, a thin film transistor, and a light emitting diode. In the display panel PN, the flexible substrate on which the thin film transistor and the light emitting diode are formed can be encapsulated by an encapsulation unit. The display panel PN includes a flexible substrate with a small thickness and a light emitting element disposed on the flexible substrate to implement the flexibility.

The flexible substrate supports various elements which configure the display panel PN. The flexible substrate can be formed of an insulating material having a very small thickness to implement the flexibility. For example, the flexible substrate can be an insulating plastic substrate selected from polyimide, polyethersulfone, polyethylene terephthalate, and polycarbonate, but is not limited thereto.

A driving thin film transistor for driving the light emitting diode can be disposed on the flexible substrate. The driving thin film transistor can be disposed in each of the plurality of sub pixels SP. For example, the driving thin film transistor includes a gate electrode, an active layer, a source electrode, and a drain electrode. The driving thin film transistor can further include a gate insulating layer which insulates the gate electrode from the active layer and also an interlayer insulating layer which insulates the gate electrode from the source electrode and the drain electrode.

The light emitting diode can be disposed on the substrate on which the driving thin film transistor is disposed. For example, when the display panel PN is an organic light emitting display panel, the display element can be an organic light emitting diode which includes an anode, an emission layer, and a cathode. For example, when the display panel PN is a liquid crystal display panel, the display element can be a liquid crystal display element.

The cover member 120 can be disposed on the display panel PN. The cover member 120 is a shape corresponding to the display panel PN and is disposed so as to cover the display panel PN. The cover member 120 can protect the display panel PN from impacts, moisture, heat, and scratches from the outside. The cover member 120 can be, for example, tempered glass, but is not limited thereto, and can also be a flexible plastic based cover which is foldable for the small thickness and flexibility of the display device 100.

Further, the cover member 120 can have a multi-layered structure in which various functional layers are laminated. For example, the cover member 120 can include various functional layers such as external light reflection reducing layer, a UV blocking layer, or a hard coating layer. Further, a touch panel which forms a touch sensor can be optionally disposed between the display panel PN and the cover member 120 as needed.

The support member 130 can be disposed below the display panel PN. The support member 130 supports the display panel PN and protects the display panel PN from external moisture, heat, and shocks. For example, the support member 130 can be also referred to as a back plate. The support member 130 suppresses curl and static electricity of the display device 100 and is formed of a transparent organic insulating material to inspect an outer appearance of the rear surface of the display device 100. For example, the support member 130 can be formed of a plastic material, such as polymethylmetacrylate (PMMA), polycarbonate (PC), polyvinylalcohol (PVA), acrylonitirlebutadiene-styrene (ABS), polyethylene terephthalate (PET), silicone, or polyurethane (PU), but it is not limited thereto.

The polarization layer 110 can be disposed between the display panel PN and the cover member 120. The polarization layer 110 is a layer for planarizing incident light and is a film having a predetermined level of light transmittance to absorb external light and reflected light thereof to suppress degradation of a contrast ratio. Specifically, the display panel PN includes various metal materials applied to the semiconductor element, the wiring line, and the organic light emitting diode. Therefore, the external light incident onto the display panel PN can be reflected from the metal material so that the visibility of the display device 100 can be reduced due to the reflection of the external light. Therefore, the polarization layer 110 is disposed to suppress reflection of the external light, thereby increasing outdoor visibility of the display device 100.

The adhesive layer ADH1 including an opening which overlaps the through-hole TH is disposed between the polarization layer 110 and the cover member 120 to fix the polarization layer 110 and the cover member 120 to each other. For example, a width of the opening can be the same as a width of the through-hole TH.

The adhesive layer ADH1 minimizes foreign materials or bubbles generated between the polarization layer 110 and the cover member 120 and uses an adhesive which is optically clear, such as an optically clear adhesive (OCA) or an optical clear resin (OCR), but is not limited thereto.

Referring to FIGS. 5 and 6, the display panel PN can include a through-hole TH which is enclosed by the display area AA in the display area AA. At this time, the through-hole TH is not only disposed in the display panel PN, but also extends from the display panel PN to the support member 130 and the polarization layer 110.

In the display device 100 according to the example embodiment of the present disclosure, the optical device CAM can be inserted into the through-hole TH.

However, there is a clearance tolerance between the through-hole and the optical device, taking into account the tolerance during the assembly. In the related art, side walls of the display panel, the polarization layer, and the support member are exposed from the through-hole due to the clearance tolerance and light leakage that the light is leaked through the top of the display panel occurs due to the clearance tolerance. The light leakage is recognized as a viewing angle through the optical device to degrade a capturing quality of the optical device and deteriorate the display performance.

Therefore, in the display device 100 according to the example embodiment of the present disclosure, the light shielding member 140 is disposed below the support member 130 to reduce the distance of the clearance tolerance between the through-hole TH and the optical device CAM. Further, the light shielding member 140 suppresses the exposure of the side walls of the display panel PN, the polarization layer 110, and the support member 130 through the through-hole TH. Therefore, the light leakage that light is exposed from the side surface of the through-hole TH is suppressed to improve a display performance and a display quality.

The light shielding member 140 is disposed so as to overlap the through-hole TH and includes a first hole H1 and a second hole H2 having widths smaller than the width of the through-hole TH. Specifically, the light shielding member 140 includes a first part P1, a second part P2, and a third part P3. The first part P1 is disposed below the support member 130 and has a first hole H1. The second part P2 protrudes toward a center axis of the through-hole TH from the side surface of the polarization layer 110 and has a second hole H2 which is concentric with the first hole H1. The third part P3 connects the first part P1 and the second part P2. At this time, the first hole H1 is wider than the second hole H2. For example, the width of the first hole H1 is larger than the width of the optical device CAM and the width of the second hole H2 is smaller than the width of the optical device CAM.

Accordingly, the optical device CAM is located inside the first hole H1 and is not inserted into the second hole H2. Accordingly, the optical device CAM is stably fastened into the first hole H1. Further, the optical device CAM is disposed so as to overlap at least a part of the second part P2 of the light shielding member 140. For example, the clearance tolerance between the through hole TH and the optical device CAM is blocked by the protruding second part P2 of the light shielding member 140 in front of the display device 100. Accordingly, the side wall of the through-hole TH is blocked by the light shielding member 140 to suppress light leakage through the side wall of the through-hole TH.

Further, the light shielding member 140 also protects the support member 130 from external shocks which can be applied during the manufacturing process of the display device.

In addition, the light shielding member 140 also serves as a heat dissipation plate which discharges heat generated in the display panel PN to the outside. The light shielding member 140 can be formed of stainless steel (SUS), stainless steel (SUS) containing other metals such as nickel (Ni), or a metal material such as iron (Fe), aluminum (Al), copper (Cu), or magnesium (Mg). Further, the light shielding member 140 is formed in the form of a tape to be configured as a light shielding tape. As the light shielding member 140, the metal material such as aluminum (Al) can be applied. For example, aluminum (Al) performs heat dissipation and reflection functions to not only discharge heat generated in the display panel PN to the outside, but also suppress light leakage on the side wall of the through-hole TH.

The display panel PN, the support member 130, and the polarization layer 110 are spaced apart from the light shielding member 140 to be located outside the third part P3 of the light shielding member 140. For example, there can be a clearance tolerance between the display panel PN, the support member 130, and the polarization layer 110 and the third part P3 of the light shielding member 140, taking into account the tolerance during the assembly.

In the meantime, when an empty space was remained between the optical device and the cover member, the optical device shown excellent transmittance, but there was a problem in that the display quality was deteriorated, such as smearing or blurring due to foreign materials, such as dust or bubbles entering through the through-hole.

Therefore, in the display device 100 according to the example embodiment of the present disclosure, the empty space between the optical device CAM and the cover member 120 can be filled with the filling member 150.

The filling member 150 can be optically clear material and specifically, the filling member 150 can include an optically clear resin (OCR), but is not limited thereto and can include a material which is optically clear and is curable.

The empty space between the optical device CAM and the cover member 120 is filled with the filling member 150 to suppress foreign materials, such as dust, or moisture from entering the top of the optical device CAM through the through-hole TH. Accordingly, the foreign materials or bubbles (air gaps) above the optical device CAM are suppressed to improve the reliability of the display device 100. Further, the moisture permeation above the optical device CAM is suppressed to improve the reliability of the display device 100. Further, the optically clear resin is applied as the filling member 150 to maintain the transmittance above the optical device CAM to improve the display quality of the display device 100.

For example, the filling member 150 can be in contact with the side surface of the second part P2 and the top surface of the second part P2 of the light shielding member 140 which is adjacent to the through-hole TH. Further, the filling member 150 can also be filled in the clearance tolerance between the display panel PN, the support member 130, and the polarization layer 110 and the third part P3 of the light shielding member 140, but is not limited thereto. Therefore, the filling member 150 can also be provided only between the upper portion of the optical device CAM and the cover member 120.

According to the example embodiment of the present disclosure, the light shielding member 140 is disposed below the support member 130 so that the side wall of the through-hole TH is blocked by the light shielding member 140 to suppress the light leakage on the side wall of the through hole TH. Further, the empty space between the optical device CAM and the cover member 120 is filled with the filling member 150 to suppress foreign materials, such as dust, or moisture from entering the top of the optical device CAM through the through-hole TH, thereby suppressing the foreign materials or bubbles. Thus, according to the example embodiment of the present disclosure, the quality and the reliability of the display device 100 can be improved.

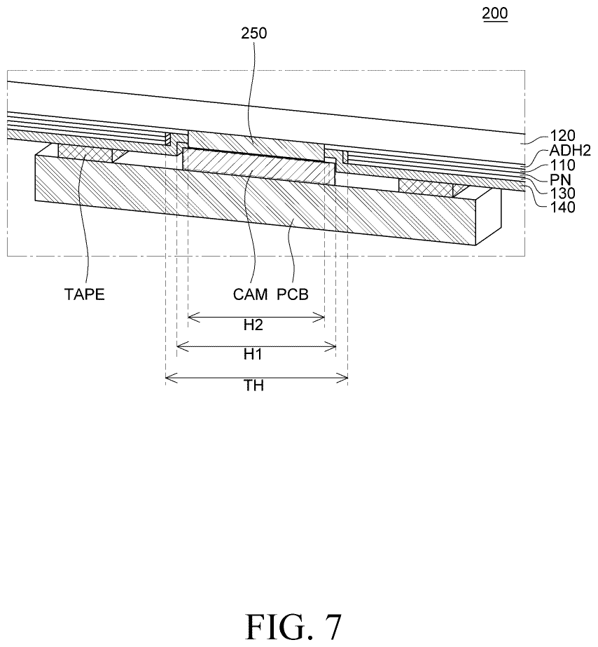

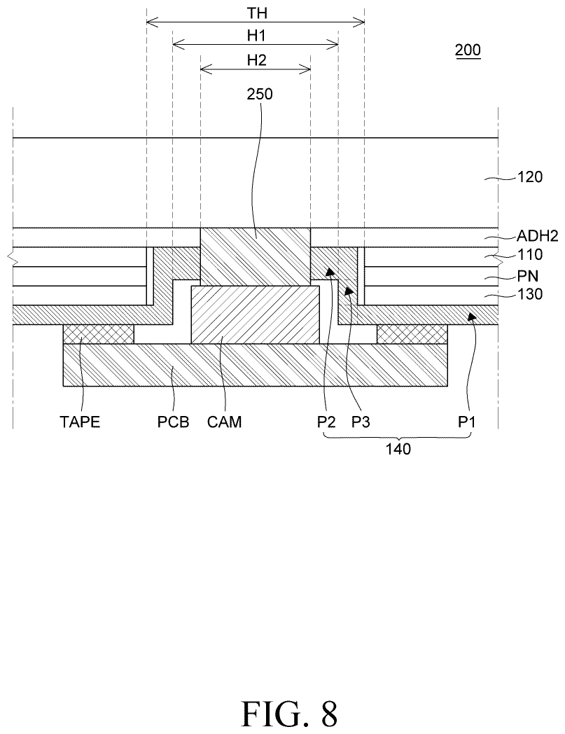

FIG. 7 is a perspective view of a display device according to another example embodiment of the present disclosure. FIG. 8 is a cross-sectional view of a display device according to another example embodiment of the present disclosure. FIGS. 7 and 8 are substantially the same as FIGS. 1 to 6 except for an adhesive layer and a filling member. Therefore, for the convenience of description, a redundant description except for the adhesive layer and the filling member will be omitted or may be briefly provided.

Referring to FIGS. 7 and 8, in the display device 200 according to another example embodiment of the present disclosure, the adhesive layer ADH2 protrudes toward the through-hole TH so that one end of the adhesive layer ADH2 facing toward the through-hole TH is located on the same line as one end of the second part P2 of the light shielding member 140 close to a center axis of the through-hole TH.

In the display device 200 according to another example embodiment of the present disclosure, the empty space between the optical device CAM and the cover member 120 is filled with the filling member 250.

At this time, the side surface of the second part P2 of the light shielding member 140 and the side surface of the adhesive layer ADH2 are located on the same line. Therefore, when the filling member 250 is applied, the filling member 250 is disposed so as to be in contact with the side surface of the adhesive layer ADH2 and the side surface of the second part P2 of the light shielding member 140 adjacent to the through hole TH.

Accordingly, the empty space between the optical device CAM and the cover member 120 is filled with the filling member 250 to suppress foreign materials, such as dust, or moisture from entering the top of the optical device CAM through the through-hole TH. Therefore, the reliability of the display device 200 can be improved. Further, the optically clear resin is applied as the filling member 250 to maintain the transmittance above the optical device CAM to improve the display quality of the display device 100.

Further, the side surface of the second part P2 of the light shielding member 140 and the side surface of the adhesive layer ADH2 are located on the same line. Therefore, when the filling member 250 is applied, the filling member 250 is not filled in the clearance tolerance between the display panel PN, the support member 130, and the polarization layer 110 and the third part P3 of the light shielding member 140. Accordingly, a height of the filling member 250 above the optical device CAM can be uniformly set.

For example, when the filling member is filled in the clearance tolerance between the display panel, the support member, and the polarization layer and the light shielding member, there was a problem of in that process cost increased because an excessive amount of filling member is applied by taking into account an amount flowing to the clearance tolerance.

However, in the display device 200 according to another example embodiment of the present disclosure, the adhesive layer ADH2 extends so as to be disposed on the same line as the side surface of the second part P2 of the light shielding member 140. Accordingly, the filling member 250 is not filled in the clearance tolerance between the display panel PN, the support member 130, and the polarization layer 110 and the third part P3 of the light shielding member 140. Therefore, an amount of applied filling member 250 is precisely controlled to set a uniform height of the filling member 250 above the optical device CAM. Accordingly, the display device 200 with a further improved display quality is provided and the process cost is also reduced.

The example embodiments of the present disclosure can also be described as follows:

According to an aspect of the present disclosure, a display device including a display panel which includes a display area, an optical area which is enclosed by the display area and includes a through-hole, and a non-display area which encloses the display area, a cover member on the display panel, a support member disposed below the display panel, a light shielding member disposed below the support member, and an optical device inserted into the through-hole, a filling member is filled between the optical device and the cover member.

The display device can further include a polarization layer disposed between the display panel and the cover member, and an adhesive layer which is disposed between the polarization layer and the cover member and includes an opening overlapping the through-hole, the through-hole of the display panel can be disposed so as to extend to the support member and the polarization layer.

The light shielding member can include a first part which is disposed below the support member and includes a first hole disposed so as to overlap the through-hole, a second part which protrudes from the side surface of the polarization layer toward the through-hole and includes a second hole which is concentric with the first hole, and a third part which connects the first part and the second part.

A width of the first hole can be smaller than a width of the through-hole and can be larger than a width of the second hole.

A width of the opening is equal to a width of the through-hole and the filling member can be disposed so as to be in contact with a side surface of the second part and a top surface of the second part of the light shielding member which is adjacent to the through-hole.

The adhesive layer can protrude toward the through-hole so that one end of the adhesive layer facing toward the through-hole is located on the same line as one end of the second part of the light shielding member close to a center axis of the through-hole.

A width of the opening can be smaller than a width of the through-hole and the filling member can be in contact with the side surface of the adhesive layer and the side surface of the second part of the light shielding member adjacent to the through-hole.

The display panel, the support member, and the polarization layer can be spaced apart from the third part of the light shielding member and can be located outside the third part.

The light shielding member can be formed of a metal material or a light shielding tape.

The filling member can include an optically clear resin.

According to another aspect of the present disclosure, a display device include a display panel which includes a display area, an optical area which is enclosed by the display area and includes a through-hole, and a non-display area which encloses the display area, a cover member on the display panel, an adhesive layer which bonds the display panel and the cover member and includes an opening overlapping the through-hole, a light shielding member which includes a first part which is disposed below the display panel and has a first hole disposed so as to overlap the through-hole, a second part which protrudes toward the through-hole below the adhesive layer and includes a second hole which is concentric with the first hole, and a third part which connects the first part and the second part, and a filling member which fills the opening and a side surface of the second part, a width of the first hole is smaller than a width of the through-hole and is larger than a width of the second hole, and an optical device which is inserted into the first hole is included in the display device.

The display device can further include a polarization layer between the display panel and the adhesive layer, and a support member between the display panel and the first part, the through-hole of the display panel can be disposed so as to extend to the support member and the polarization layer.

The filling member can include an optically clear resin.

A width of the opening and a width of the through-hole can be equal to each other.

A width of the opening and a width of the second hole can be equal to each other.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a display panel which includes a display area, an optical area which is enclosed by the display area and includes a through-hole, and a non-display area disposed adjacent to the display area;
a cover member disposed on the display panel;
a support member disposed below the display panel;
a light shielding member disposed below the support member; and
an optical device inserted into the through-hole,
wherein a filling member is filled between the optical device and the cover member.

2. The display device according to claim 1, further comprising:
a polarization layer disposed between the display panel and the cover member; and
an adhesive layer which is disposed between the polarization layer and the cover member and includes an opening overlapping the through-hole,
wherein the through-hole of the display panel is disposed so as to extend to the support member and the polarization layer.

3. The display device according to claim 2, wherein the light shielding member includes:
a first part which is disposed below the support member and includes a first hole disposed so as to overlap the through-hole,
a second part which protrudes from the side surface of the polarization layer toward the through-hole and includes a second hole which is concentric with the first hole, and
a third part which connects the first part and the second part.

4. The display device according to claim 3, wherein a width of the first hole is smaller than a width of the through-hole and is larger than a width of the second hole.

5. The display device according to claim 3, wherein a width of the opening of the adhesive layer is equal to a width of the through-hole, and
wherein the filling member is disposed so as to be in contact with a side surface of the second part of the light shielding member and a top surface of the second part of the light shielding member which is adjacent to the through-hole.

6. The display device according to claim 3, wherein a width of the opening of the adhesive layer and a width of the second hole are equal to each other.

7. The display device according to claim 3, wherein the adhesive layer protrudes toward the through-hole so that one end of the adhesive layer facing toward the through-hole is located on a same line as one end of the second part of the light shielding member close to a center axis of the through-hole.

8. The display device according to claim 7, wherein a width of the opening of the adhesive layer is smaller than a width of the through-hole and the filling member is in contact with the side surface of the adhesive layer and the side surface of the second part of the light shielding member adjacent to the through-hole.

9. The display device according to claim 3, wherein the display panel, the support member, and the polarization layer are spaced apart from the third part of the light shielding member, and are located outside the third part of the light shielding member.

10. The display device according to claim 1, wherein the light shielding member includes a metal material or a light shielding tape.

11. The display device according to claim 1, wherein the filling member includes an optically clear resin.

12. A display device comprising:
a display panel which includes a display area, an optical area which is enclosed by the display area and includes a through-hole, and a non-display area disposed adjacent to the display area;
a cover member disposed on the display panel;
an adhesive layer which bonds the display panel and the cover member and includes an opening overlapping the through-hole;
a light shielding member which includes a first part which is disposed below the display panel and has a first hole disposed so as to overlap the through-hole, a second part which protrudes toward the through-hole below the adhesive layer and includes a second hole which is concentric with the first hole, and a third part which connects the first part and the second part; and
a filling member which fills the opening of the adhesive layer and a side surface of the second part of the light shielding member,
wherein a width of the first hole is smaller than a width of the through-hole and is larger than a width of the second hole, and
wherein an optical device is inserted into the first hole.

13. The display device according to claim 12, further comprising:
a polarization layer between the display panel and the adhesive layer; and
a support member between the display panel and the first part,
wherein the through-hole of the display panel is disposed so as to extend to the support member and the polarization layer.

14. The display device according to claim 12, wherein the filling member includes an optically clear resin.

15. The display device according to claim 12, wherein a width of the opening of the adhesive layer and a width of the through-hole of the display panel are equal to or substantially equal to each other.

16. The display device according to claim 12, wherein a width of the opening of the adhesive layer and a width of the second hole are equal to each other.

17. The display device according to claim 12, wherein the optical device that is inserted into the first hole is included in the display device.

18. The display device according to claim 12, wherein the optical device is not inserted into the second hole.

19. The display device according to claim 12, further comprising:
a printed circuit board disposed under the optical device and attached to the light shielding member,
wherein a top surface of the optical device directly contacts a bottom surface of the filling member while a space is created between the optical device, the light shielding member and the printed circuit board.

20. The display device according to claim 19, wherein the space created between the optical device, the light shielding member and the printed circuit board includes a step shape.
